(19) United States
(12) Patent Application Publication
(10) Pub. No.: US 2025/0149402 A1
(43) Pub. Date: May 8, 2025

(54) SEMICONDUCTOR PACKAGE STRUCTURE

(71) Applicant: TONG HSING ELECTRONIC INDUSTRIES, LTD., Taipei City (TW)

(72) Inventor: Ting-An Yang, Taipei City (TW)

(21) Appl. No.: 18/419,517

(22) Filed: Jan. 22, 2024

(30) Foreign Application Priority Data
Nov. 3, 2023 (TW) 112142327

(51) Int. Cl. H01L 23/42; H01L 23/00; H01L 23/31; H01L 23/495; H01L 25/07

(52) U.S. Cl. CPC H01L 23/42; H01L 23/3107; H01L 23/49562; H01L 24/32; H01L 25/074; H01L 2224/32245

(57) ABSTRACT

A semiconductor package structure includes a conductive substrate, a chip, a plurality of conductive spacers, a lead frame, and an encapsulant that covers the above components. The conductive substrate has a chip-bonding surface and a heat-dissipation surface that is opposite to the chip-bonding surface. The chip is disposed on the chip-bonding surface of the conductive substrate, and has a plurality of connection pads arranged away from the conductive substrate. The conductive spacers are respectively disposed on the connection pads, and ends of the conductive spacers are arranged away from the conductive substrate and are coplanar with each other. The lead frame is connected to the ends of the conductive spacers in a flip-chip manner, and has an exposed surface. The heat-dissipation surface and the exposed surface are exposed from the encapsulant.

### CROSS-REFERENCE TO RELATED PATENT APPLICATION

This application claims the benefit of priority to Taiwan Patent Application No. 112142327, filed on Nov. 3, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a semiconductor package structure.

### BACKGROUND OF THE DISCLOSURE

Interior components of a conventional semiconductor package structure often have a height difference therebetween, such that a connection stability of the interior components is affected and cannot be easily maintained. For example, after the conventional semiconductor package structure undergoes a thermal cycling environment of a packaging process, cracks may be formed in an interior of the conventional semiconductor package structure.

### SUMMARY OF THE DISCLOSURE

In response to the above-referenced technical inadequacies, the present disclosure provides a semiconductor package structure for effectively improving on the issues associated with conventional semiconductor package structures.

In order to solve the above-mentioned problems, one of the technical aspects adopted by the present disclosure is to provide a semiconductor package structure, which includes a conductive substrate, a first chip, a second chip, a plurality of conductive spacers, a lead frame, and an encapsulant. The conductive substrate has a chip-bonding surface and a heat-dissipation surface that is opposite to the chip-bonding surface. The first chip is disposed on the chip-bonding surface of the conductive substrate and has a plurality of first connection pads that are arranged away from the conductive substrate. The second chip is disposed on one of the first connection pads of the first chip and has a plurality of second connection pads that are arranged away from the conductive substrate. The conductive spacers include a first conductive spacer disposed on another of the first connection pads and a plurality of second conductive spacers that are respectively disposed on the second connection pads. Moreover, a thickness of the first conductive spacer is greater than a thickness of each of the second conductive spacers, and an end of the first conductive spacer and ends of the second conductive spacers are arranged away from the conductive substrate and are coplanar with each other. The lead frame is connected to the end of the first conductive spacer and the ends of the second conductive spacers in a flip-chip manner and has an exposed surface. The encapsulant covers the conductive substrate, the first chip, the second chip, the first conductive spacer, the second conductive spacers, and the lead frame, and the exposed surface and the heat-dissipation surface are exposed from the encapsulant.

In order to solve the above-mentioned problems, another one of the technical aspects adopted by the present disclosure is to provide a semiconductor package structure, which includes a conductive substrate, a chip, a plurality of conductive spacers, a lead frame, and an encapsulant. The conductive substrate has a chip-bonding surface and a heat-dissipation surface that is opposite to the chip-bonding surface. The chip is disposed on the chip-bonding surface of the conductive substrate and has a plurality of connection pads that are arranged away from the conductive substrate. The conductive spacers are respectively disposed on the connection pads, and ends of the conductive spacers are arranged away from the conductive substrate and are coplanar with each other. The lead frame is connected to the ends of the conductive spacers in a flip-chip manner and has an exposed surface. The encapsulant covers the conductive substrate, the chip, the conductive spacers, and the lead frame. The exposed surface and the heat-dissipation surface are exposed from the encapsulant.

In order to solve the above-mentioned problems, yet another one of the technical aspects adopted by the present disclosure is to provide a semiconductor package structure, which includes a conductive substrate, a plurality of conductive carriers, a chip, a plurality of conductive spacers, a lead frame, and an encapsulant. The conductive substrate has a chip-bonding surface and a heat-dissipation surface that is opposite to the chip-bonding surface. The conductive carriers are arranged adjacent to the conductive substrate. The chip is disposed on the chip-bonding surface of the conductive substrate and has a plurality of connection pads that are arranged away from the conductive substrate. The conductive spacers are respectively disposed on at least one of the connection pads and at least one of the conductive carriers, and ends of the conductive spacers are coplanar with each other. The lead frame is connected to the ends of the conductive spacers in a flip-chip manner and has an exposed surface. The encapsulant covers the conductive substrate, the conductive carriers, the chip, the conductive spacers, and the lead frame. The exposed surface, the heat-dissipation surface, and a surface of each of the conductive carriers are exposed from the encapsulant.

Therefore, through the cooperation of components in the semiconductor package structure of the present disclosure (e.g., the ends of the conductive spacers being coplanar with each other for allowing the lead frame to be assembled thereon in a flip-chip manner), the influence from a height difference of the components can be effectively reduced, thereby improving the connection stability of the components.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a semiconductor package structure according to a first embodiment of the present disclosure;

FIG. 2 is a schematic perspective view of the semiconductor package structure from another angle of view according to the first embodiment of the present disclosure;

FIG. 3 is a schematic cross-sectional view taken along line III-III of FIG. 1;

FIG. 4 is a schematic perspective view showing the semiconductor package structure of FIG. 1 with an encapsulant being omitted;

FIG. 5 is a schematic exploded view of FIG. 4;

FIG. 6 is a schematic exploded view of a part of FIG. 5;

FIG. 7 is a schematic perspective view of the semiconductor package structure according to a second embodiment of the present disclosure;

FIG. 8 is a schematic cross-sectional view taken along line VIII-VIII of FIG. 7;

FIG. 9 is a schematic perspective view showing the semiconductor package structure of FIG. 7 with the encapsulant being omitted;

FIG. 10 is a schematic exploded view of FIG. 9;

FIG. 11 is a schematic perspective view of the semiconductor package structure according to a third embodiment of the present disclosure;

FIG. 12 is a schematic perspective view showing the semiconductor package structure of FIG. 11 with the encapsulant being omitted;

FIG. 13 is a schematic cross-sectional view taken along line XIII-XIII of FIG. 11; and

FIG. 14 is a schematic perspective view showing the semiconductor package structure in another configuration with the encapsulant being omitted according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

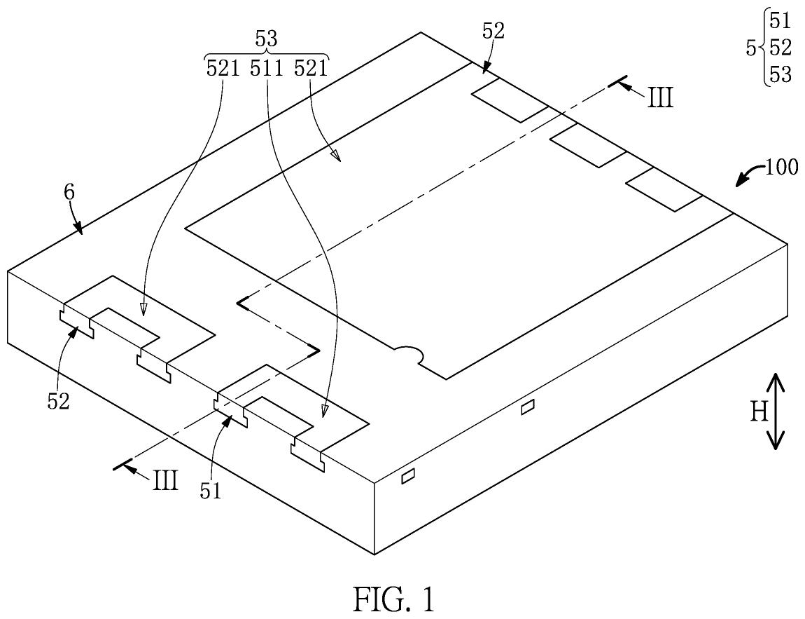

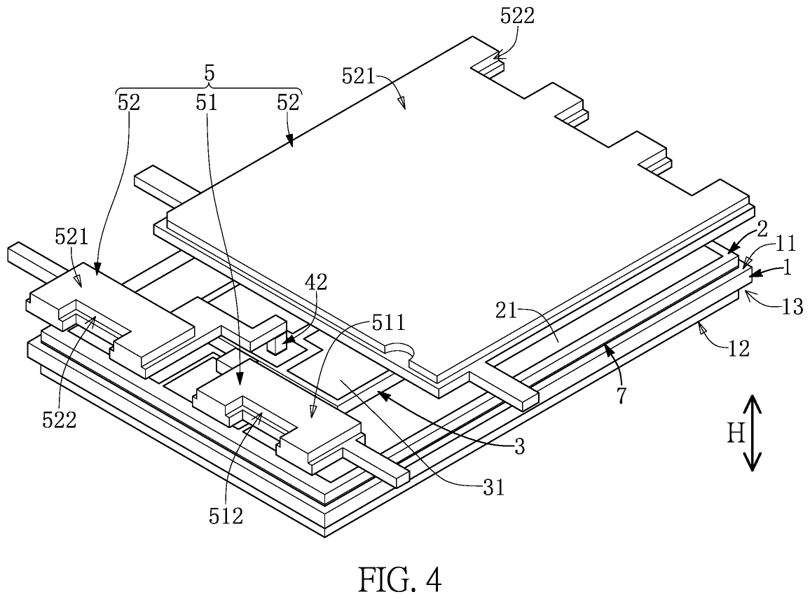

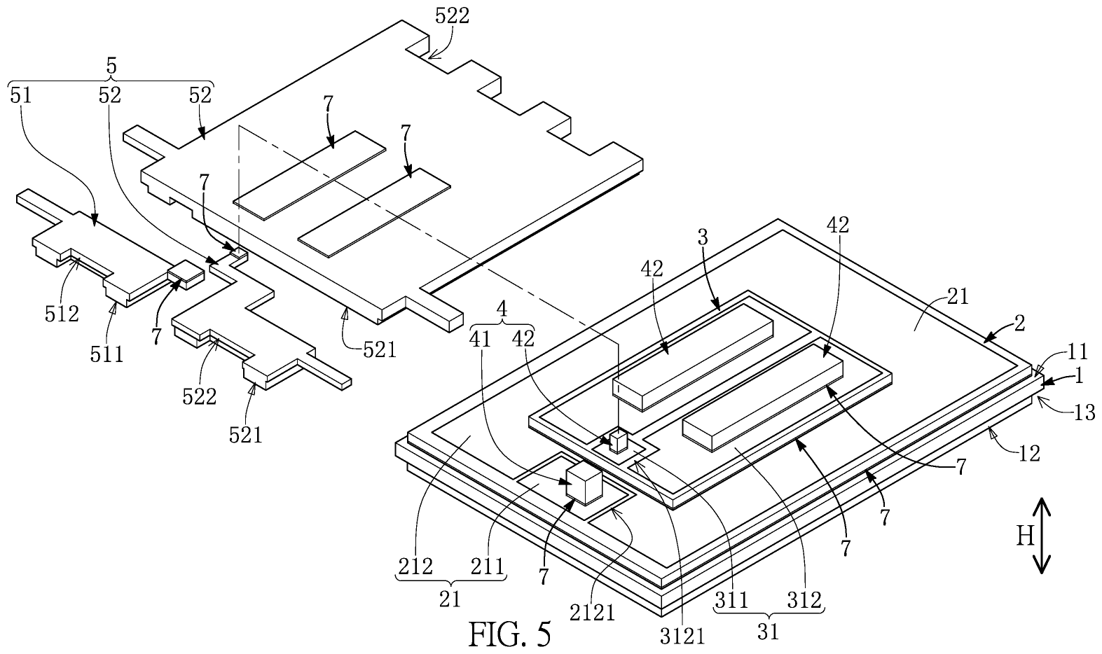

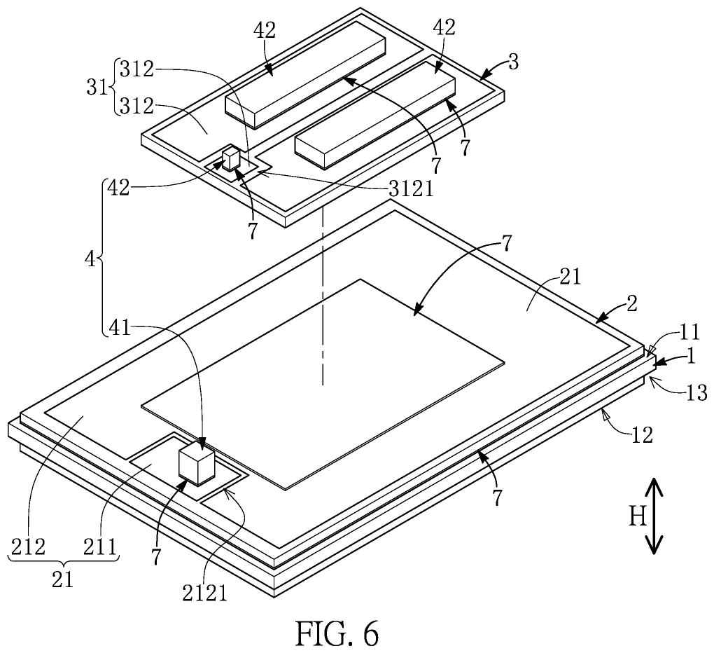

Referring to FIG. 1 to FIG. 6, a first embodiment of the present disclosure is provided. As shown in FIG. 1 to FIG. 3, the present disclosure provides a semiconductor package structure 100 that can be a power quad flat no-lead (PQFN) package structure, but the present disclosure is not limited thereto. The semiconductor package structure 100 in the present embodiment includes a conductive substrate 1, a first chip 2 disposed on the conductive substrate 1, a second chip 3 disposed on the first chip 1, a plurality of conductive spacers 4 disposed on the first chip 2 and the second chip 3, a lead frame 5 connected to the conductive spacers 4, and an encapsulant 6 that covers the above component (or that enables the above components to be embedded therein).

It should be noted that the semiconductor package structure 100 in the present embodiment further includes a plurality of conductive bonding layers 7, and any two of the conductive substrate 1, the first chip 2, the second chip 3, the conductive spacers 4, and the lead frame 5 connected to each other (or having a connection requirement) are preferably connected through one of the conductive bonding layers 7, thereby establishing an electrical connection therebetween. Accordingly, the semiconductor package structure 100 does not need to have any wiring structure covered by (or embedded in) the encapsulant 6.

Moreover, the conductive bonding layers 7 in the present embodiment are made of a same material and can be adjusted or changed according to design requirements, but the present disclosure is not limited thereto. For example, any one of the conductive bonding layers 7 in the present embodiment can be conductive paste or conductive glue, so that the semiconductor package structure 100 does not need to have any soldering structure covered by (or embedded in) the encapsulant 6, such as to prevent cracking from occurring due to a soldering structure. However, in other embodiments of the present disclosure not shown in the drawings, at least one of the conductive bonding layers 7 can be made of a soldering material according to design requirements.

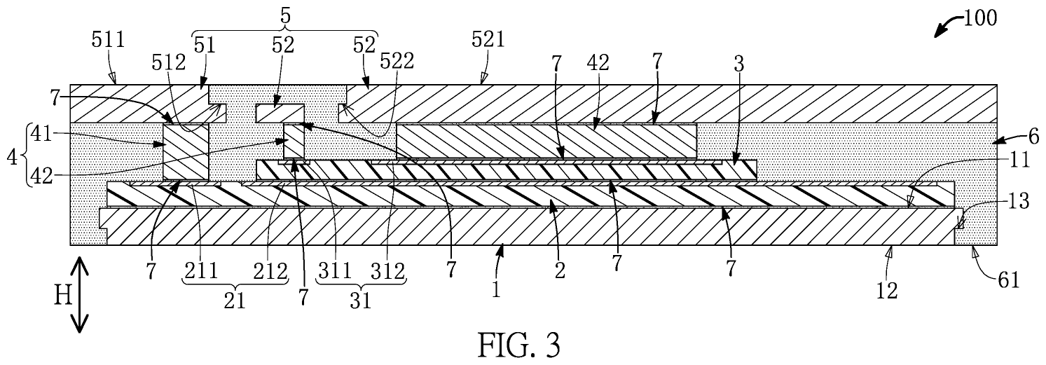

As shown in FIG. 3 to FIG. 6, the conductive substrate 1 is flat and has a chip-bonding surface 11 and a heat-dissipation surface 12 that is opposite to the chip-bonding surface 11. The conductive substrate 1 preferably has a half-etching slot 13 surrounding the heat-dissipation surface 12. In the present embodiment, the conductive substrate 1 can be a copper substrate or an aluminum substrate, but the present disclosure is not limited thereto.

In the present embodiment, a size of the first chip 2 is slightly smaller than or substantially equal to a size of the chip-bonding surface 11, and is greater than a size of the second chip 3. The first chip 2 can be a silicon carbide (SiC) chip or a gallium nitride (GaN) chip, and the second chip 3 can be a metal oxide semiconductor field effect transistor (MOSFET) chip, but the present disclosure is not limited thereto.

Specifically, the first chip 2 is disposed on the chip-bonding surface 11 of the conductive substrate 1. The first chip 2 in the present embodiment is connected to the chip-bonding surface 11 through one of the conductive bonding layers 7 for being electrically coupled to each other. The first chip 2 has a plurality of first connection pads 21 that are arranged away from the conductive substrate 1. The first connection pads 21 are spaced apart from each other and are substantially coplanar with each other.

In the present embodiment, the first connection pads 21 include a first inner pad 211 and a first outer pad 212 that is arranged around the first inner pad 211. Specifically, an area of the first outer pad 212 is greater than (e.g., at least ten times of) an area of the first inner pad 211, and the first outer pad 212 has a first notch 2121 recessed in an edge thereof, thereby allowing the first inner pad 211 to be received (or entirely arranged) in the first notch 2121. Moreover, one edge of the first inner pad 211 is flush with the edge of the first outer pad 212, and the other three edges of the first inner pad 211 face toward an inner wall of the first notch 2121 of the first outer pad 212.

The second chip 3 is disposed on one of the first connection pads 21 (e.g., the first outer pad 212) of the first chip 2. The second chip 3 in the present embodiment is connected to the first outer pad 212 through one of the conductive bonding layers 7 for being electrically coupled to each other. The second chip 3 has a plurality of second connection pads 31 that are arranged away from the conductive substrate 1. The second connection pads 31 are spaced apart from each other and are substantially coplanar with each other.

In the present embodiment, the second connection pads 31 include a second inner pad 311 and two second outer pads 312 that are arranged around the second inner pad 311. Specifically, an area of each of the two second outer pads 312 is greater than (e.g., at least six times of) an area of the second inner pad 311, and the two second outer pads 312 has a second notch 3121 recessed in one side thereof, thereby allowing the second inner pad 311 to be received (or entirely arranged) in the second notch 3121. Moreover, one edge of the second inner pad 311 is flush with the one side of the two second outer pads 312, and the other three edges of the second inner pad 311 face toward an inner wall of the second notch 3121 of the two second outer pads 312.

Moreover, the second chip 3 is stacked on a substantial center portion of the first chip 2, and the second inner pad 311 is arranged adjacent to the first inner pad 211. The area of the second inner pad 311 in the present embodiment is smaller than the area of the first inner pad 211, but the present disclosure is not limited thereto.

The conductive spacers 4 in the present embodiment are made of a same material that can be at least one of aluminum silicon carbide (AlSiC), aluminum-silicon (Al—Si) alloy, molybdenum (Mo), tungsten (W), copper-molybdenum (Cu—Mo) alloy, copper-tungsten (Cu—W) alloy, and other conductive materials. Each of the conductive spacers 4 has a coefficient of thermal expansion (CTE) that is less than 10, and the CTE of each of the conductive spacers 4 is preferably less than two times of a CTE of the first chip 2 and is preferably less than two times of a CTE of the second chip 3, but the present disclosure is not limited thereto.

Specifically, the conductive spacers 4 include a first conductive spacer 41 disposed on another of the first connection pads 21 (e.g., the first inner pad 211) and a plurality of second conductive spacers 42 that are respectively disposed on the second connection pads 31. In present embodiment, a quantity of the conductive spacers 4 is four, and one of the conductive spacers 4 disposed on the first connection pad 21 is defined as the first conductive spacer 41, while the other three of the conductive spacers 4 respectively disposed on the second connection pads 31 are defined as the second conductive spacers 42.

The first conductive spacer 41 is connected to the first inner pad 211 through one of the conductive bonding layers 7 for being electrically coupled to each other. Each of the second conductive spacers 41 is connected to the corresponding second connection pad 31 through one of the conductive bonding layers 7 for being electrically coupled to each other. Moreover, a thickness of the first conductive spacer 41 is greater than a thickness of each of the second conductive spacers 42, and an end of the first conductive spacer 41 and ends of the second conductive spacers 42 are arranged away from the conductive substrate 1 and are coplanar with each other.

The lead frame 5 is connected to the end of the first conductive spacer 41 and the ends of the second conductive spacers 42 in a flip-chip manner. In other words, the coplanar arrangement of the ends of the conductive spacers 4 in the present embodiment needs to meet the following condition: along a thickness direction H, any two of the end of the first conductive spacer 41 and the ends of the second conductive spacers 42 may have a difference therebetween that is controlled to avoid affecting the flip-chip connection of the lead frame 5.

Accordingly, the cooperation of components in the semiconductor package structure 100 of the present embodiment (e.g., the ends of the conductive spacers 4 are coplanar with each other for allowing the lead frame 5 to be assembled thereon in a flip-chip manner) can be provided to effectively reduce the influence from a height difference of the components, thereby improving the connection stability of the components.

Specifically, the lead frame 5 includes a first frame 51 and a plurality of second frames 52. The first frame 51 and the second frames 52 are spaced apart from each other. The first frame 51 is connected to the end of the first conductive spacer 41, and has a first exposed surface 511 arranged away from the first conductive spacer 41 and a first half-etching slot 512 that surrounds the first exposed surface 511.

Moreover, the second frames 52 are connected to the ends of the second conductive spacers 42, and each of the second frames 52 has a second exposed surface 521 arranged away from the corresponding second conductive spacer 42 and a second half-etching slot 522 that surrounds the second exposed surface 521. In other words, the first exposed surface 511 of the first frame 51 and the second exposed surfaces 521 of the second frames 52 in the present embodiment are jointly defined as an exposed surface 53 of the lead frame 5 (as shown in FIG. 1).

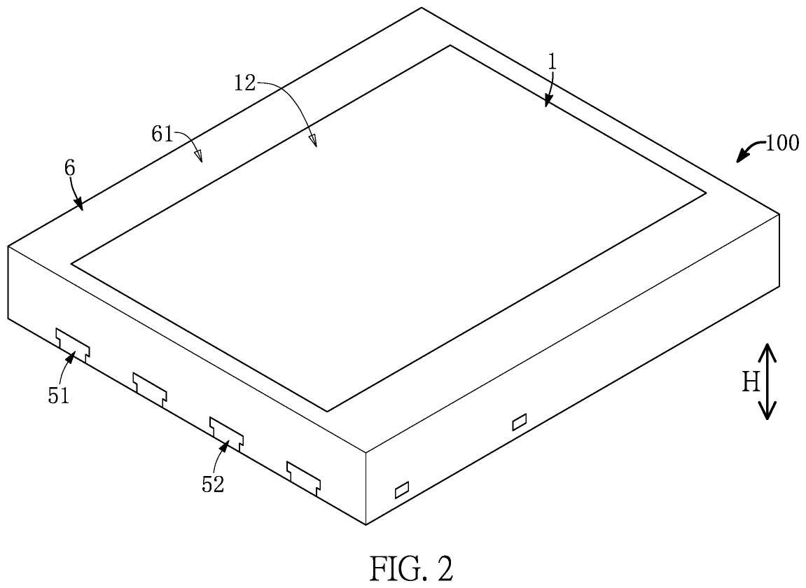

The encapsulant 6 covers the conductive substrate 1, the first chip 2, the second chip 3, the first conductive spacer 41, the second conductive spacers 42, and the lead frame 5; that is to say, the conductive substrate 1, the first chip 2, the second chip 3, the first conductive spacer 41, the second conductive spacers 42, and the lead frame 5 are embedded in the encapsulant 6. Moreover, the exposed surface 53 and the heat-dissipation surface 12 are exposed from the encapsulant 6 (as shown in FIG. 1 and FIG. 2), and are flush (or coplanar) with an outer surface 61 of the encapsulant 6. Specifically, the half-etching slot 13 of the conductive substrate 1, the first half-etching slot 512 of the first frame 51, and the second half-etching slots 522 of the second frames 52 are fully filled with the encapsulant 6, thereby enabling the encapsulant 6 to be firmly connected to the conductive substrate 1 and the lead frame 5.

### Second Embodiment

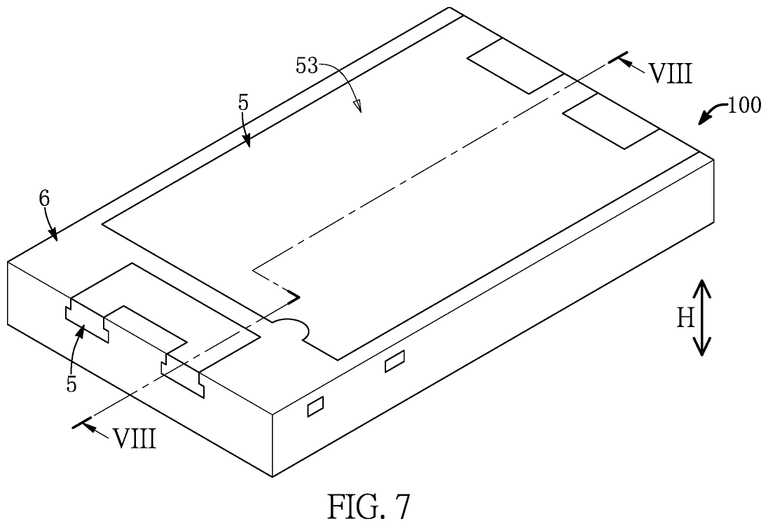

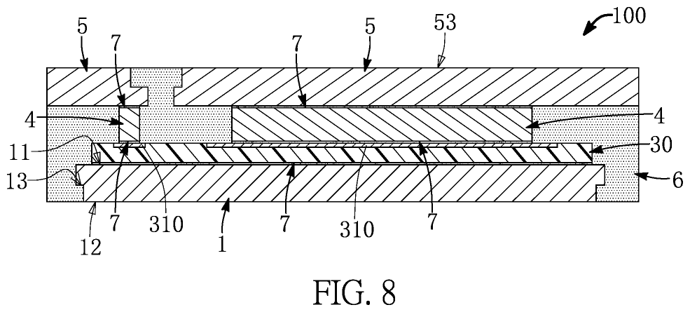

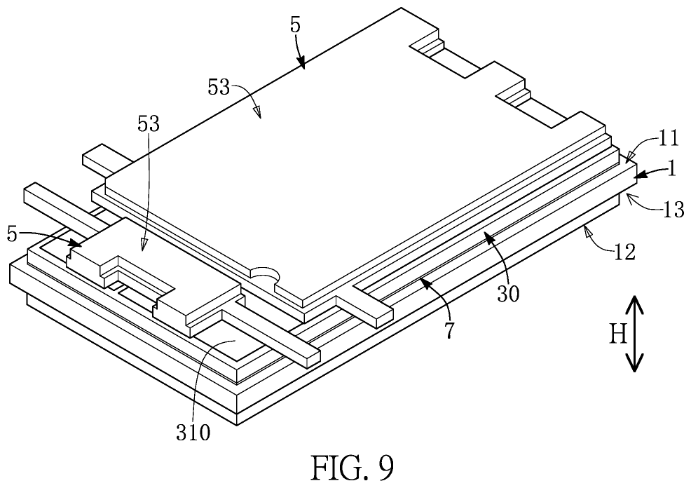

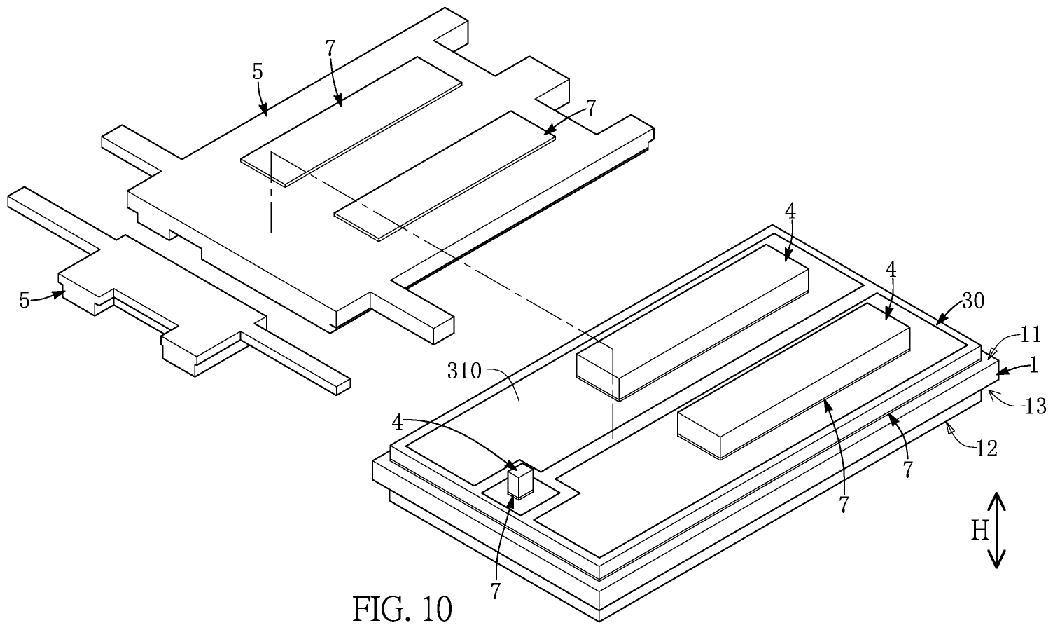

Referring to FIG. 7 to FIG. 10, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the semiconductor package structure 100 includes a conductive substrate 1, a chip 30 disposed on the conductive substrate 1, a plurality of conductive spacers 4 disposed on the chip 30, a lead frame 5 connected to the conductive spacers 4, and an encapsulant 6 that covers the above component (or that enables the above components to be embedded therein). In other words, the semiconductor package structure 100 of the present embodiment is provided without the first chip 2 or the second chip 3 of the first embodiment, and the type of the chip 30 in the present embodiment can be adjusted or changed according to design requirements (e.g., the chip 30 can be a SiC chip or a MOSFET chip), but the present disclosure is not limited thereto.

The structure of the conductive substrate 1 and the lead frame 5 as well as the material of the conductive spacers 4 (e.g., each of the conductive spacers 4 has a CTE that is less than 10 and that is less than two times of a CTE of the chip 30) in the present embodiment are substantially identical to those of the first embodiment, and are not described in the following description again for the sake of brevity.

Moreover, the semiconductor package structure 100 in the present embodiment further includes a plurality of conductive bonding layers 7, and any two of the conductive substrate 1, the chip 30, the conductive spacers 4, and the lead frame 5 connected to each other (or having a connection requirement) are preferably connected through one of the conductive bonding layers 7, thereby establishing an electrical connection therebetween. Accordingly, the semiconductor package structure 100 does not need to have any wiring structure covered by (or embedded in) the encapsulant 6.

The type (or structure) of the chip 30 in the present embodiment is similar to that of the second chip 3 described in the first embodiment. The chip 30 is disposed on the chip-bonding surface 11 of the conductive substrate 1 and has a plurality of connection pads 310 that are arranged away from the conductive substrate 1. The conductive spacers 4 are respectively disposed on the connection pads 310, and ends of the conductive spacers 4 are arranged away from the conductive substrate 1 and are coplanar with each other.

Moreover, the lead frame 5 is connected to the ends of the conductive spacers 4 in a flip-chip manner and has an exposed surface 53. The encapsulant 6 covers the conductive substrate 1, the chip 30, the conductive spacers 4, and the lead frame 5. In other words, the conductive substrate 1, the chip 30, the conductive spacers 4, and the lead frame 5 are embedded in the encapsulant 6. The exposed surface 53 and the heat-dissipation surface 12 are exposed from the encapsulant 6, and are flush (or coplanar) with an outer surface 61 of the encapsulant 6.

In summary, according to the first embodiment and the second embodiment, the configuration of the semiconductor package structure 100 provided by the present disclosure can be used to encapsulate one chip (e.g., the chip 30 of the second embodiment) or at least two chips (e.g., the first chip 2 and the second chip 3 of the first embodiment) stacked with each other. Furthermore, in other embodiments of the present disclosure not shown in the drawings, the semiconductor package structure 100 can include at least three chips 30 stacked with each other and embedded therein according to design requirements.

### Third Embodiment

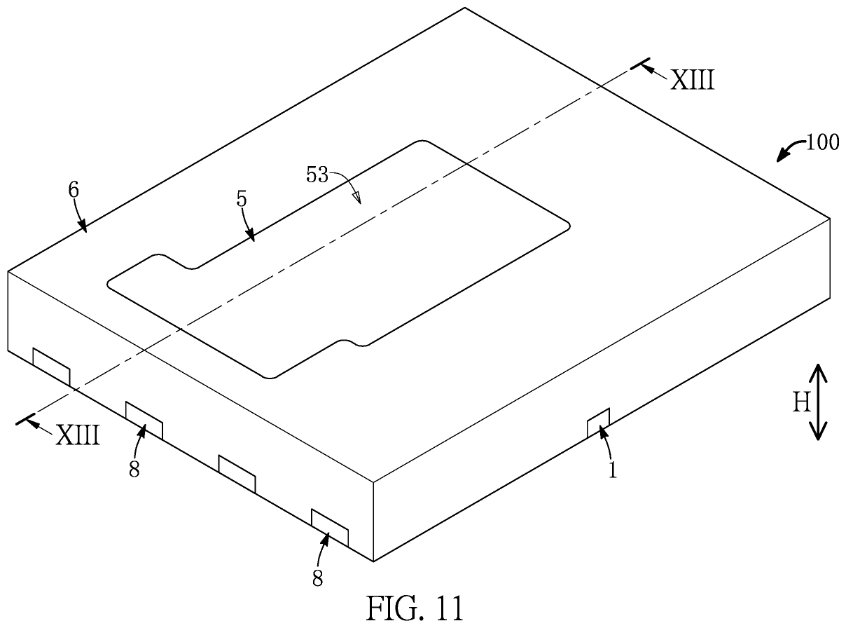

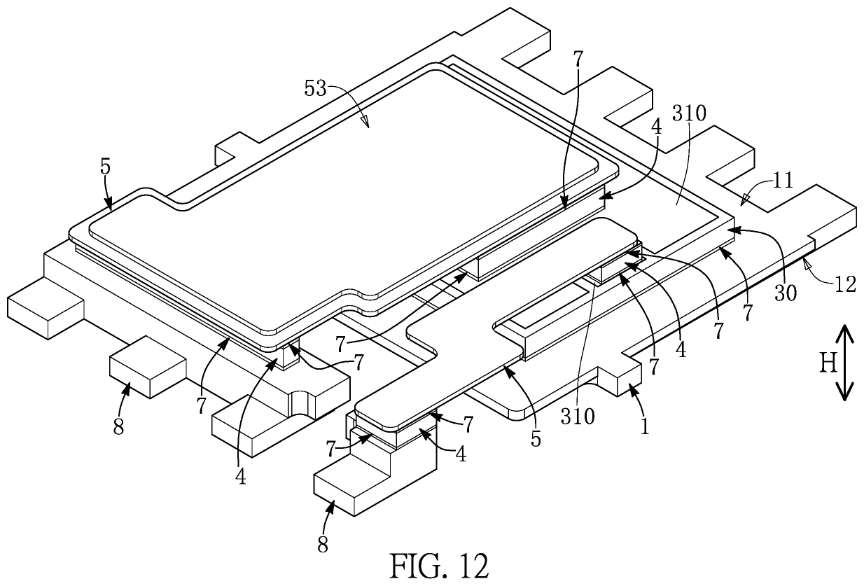

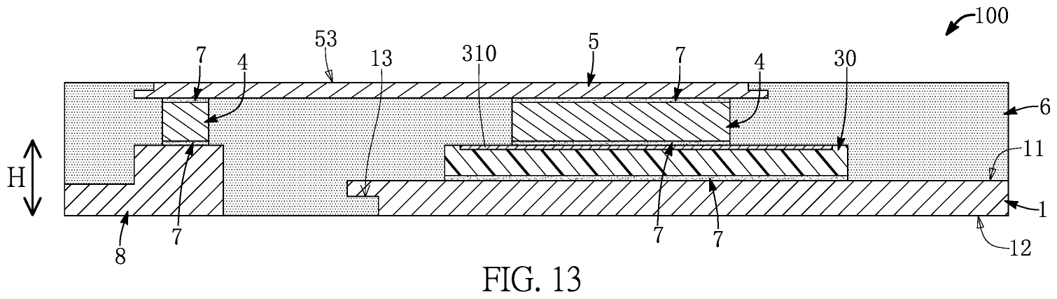

Referring to FIG. 11 to FIG. 14, a third embodiment of the present disclosure, which is similar to the second embodiment of the present disclosure, is provided. For the sake of brevity, descriptions of the same components in the second and third embodiments of the present disclosure will be omitted herein, and the following description only discloses different features between the second and third embodiments.

In the present embodiment, as shown in FIG. 11 to FIG. 13, the semiconductor package structure 100 further includes a plurality of conductive carriers 8 arranged adjacent to the conductive substrate 1. The conductive carriers 8 are embedded in the encapsulant 6, and a surface of each of the conductive carriers 8 is exposed from the encapsulant 6. The conductive carriers 8 are spaced apart from one side of the conductive substrate 1, and a thickness of each of the conductive carriers 8 can be greater than a thickness of the conductive substrate 1.

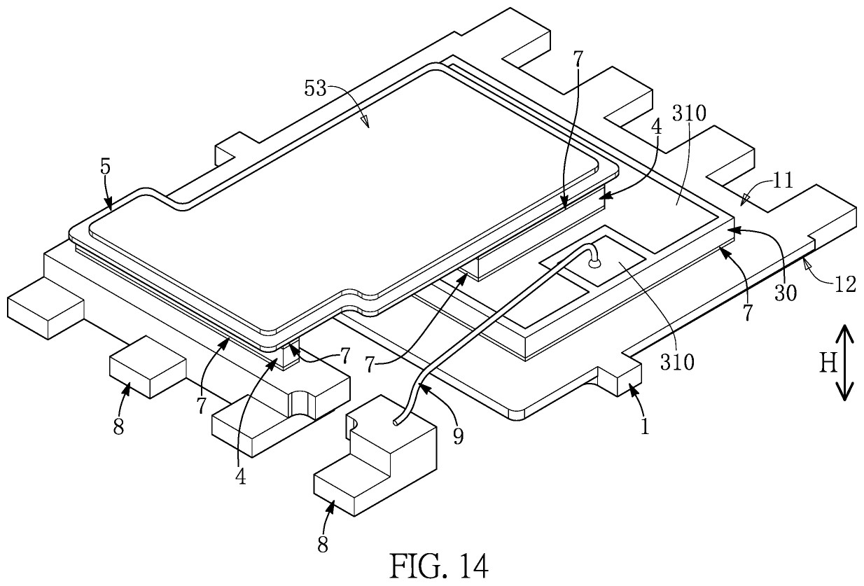

Moreover, the conductive spacers 4 are respectively disposed on the connection pads 310 and the conductive carriers 8, and ends of the conductive spacers 4 are coplanar with each other. The lead frame 5 is connected to the ends of the conductive spacers 4 in a flip-chip manner. Specifically, the lead frame 5 shown in FIG. 11 to FIG. 13 includes two frames, one of the two frames has an exposed surface 53 exposed from the encapsulant 6, and another of the two frames is entirely embedded in the encapsulant 6, but the present disclosure is not limited thereto. For example, as shown in FIG. 14, the conductive spacers 4 can be respectively disposed on one of the connection pads 310 and one of the conductive carriers 8, the lead frame 5 is a single one-piece structure, and the semiconductor package structure 100 further includes a metal wire 9 embedded in the encapsulant 6. Moreover, two ends of the metal wire 9 are respectively connected to another of the connection pads 310 and another of the conductive carriers 8.

As shown in FIG. 11 to FIG. 13, the semiconductor package structure 100 also includes a plurality of conductive bonding layers 7. Any two of the conductive substrate 1, the conductive carriers 8, the connection pads 310 of the chip 30, the conductive spacers 4, and the lead frame 5 connected to each other (or having a connection requirement) are connected through one of the conductive bonding layers 7.

### Beneficial Effects of the Embodiments

In conclusion, through the cooperation of components in the semiconductor package structure of the present disclosure (e.g., the ends of the conductive spacers being coplanar with each other for allowing the lead frame to be assembled thereon in a flip-chip manner), the influence from a height difference of the components can be effectively reduced, thereby improving the connection stability of the components.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A semiconductor package structure, comprising:
a conductive substrate having a chip-bonding surface and a heat-dissipation surface that is opposite to the chip-bonding surface;
a first chip disposed on the chip-bonding surface of the conductive substrate and having a plurality of first connection pads that are arranged away from the conductive substrate;
a second chip disposed on one of the first connection pads of the first chip and having a plurality of second connection pads that are arranged away from the conductive substrate;
a plurality of conductive spacers including a first conductive spacer disposed on another of the first connection pads and a plurality of second conductive spacers that are respectively disposed on the second connection pads, wherein a thickness of the first conductive spacer is greater than a thickness of each of the second conductive spacers, and an end of the first conductive spacer and ends of the second conductive spacers are arranged away from the conductive substrate and are coplanar with each other;
a lead frame connected to the end of the first conductive spacer and the ends of the second conductive spacers in a flip-chip manner and having an exposed surface; and
an encapsulant covering the conductive substrate, the first chip, the second chip, the first conductive spacer, the second conductive spacers, and the lead frame, wherein the exposed surface and the heat-dissipation surface are exposed from the encapsulant.

2. The semiconductor package structure according to claim 1, wherein the exposed surface and the heat-dissipation surface are flush with an outer surface of the encapsulant.

3. The semiconductor package structure according to claim 1, wherein each of the conductive spacers has a coefficient of thermal expansion (CTE) that is less than 10.

4. The semiconductor package structure according to claim 1, wherein a CTE of each of the conductive spacers is less than two times of a CTE of the first chip and is less than two times of a CTE of the second chip.

5. The semiconductor package structure according to claim 1, further comprising a plurality of conductive bonding layers, wherein any two of the conductive substrate, the first chip, the second chip, the conductive spacers, and the lead frame connected to each other are connected through one of the conductive bonding layers.

6. The semiconductor package structure according to claim 5, wherein the semiconductor package structure does not have any soldering structure covered by the encapsulant.

7. The semiconductor package structure according to claim 1, wherein the semiconductor package structure does not have any wiring structure covered by the encapsulant.

8. The semiconductor package structure according to claim 1, wherein a size of the first chip is greater than a size of the second chip, the first chip is a silicon carbide (SiC) chip or a gallium nitride (GaN) chip, and the second chip is a metal oxide semiconductor field effect transistor (MOSFET) chip.

9. The semiconductor package structure according to claim 1, wherein the conductive substrate has a half-etching slot that surrounds the heat-dissipation surface and that is fully filled with the encapsulant.

10. The semiconductor package structure according to claim 1, wherein the lead frame includes:
a first frame connected to the end of the first conductive spacer and having a part of the exposed surface that is defined as a first exposed surface, wherein the first frame has a first half-etching slot that surrounds the first exposed surface and that is fully filled with the encapsulant; and
a plurality of second frames connected to the ends of the second conductive spacers and each having another part of the exposed surface that is defined as a second exposed surface, wherein each of the second frames has a second half-etching slot that surrounds the second exposed surface thereof and that is fully filled with the encapsulant.

11. A semiconductor package structure, comprising:
a conductive substrate having a chip-bonding surface and a heat-dissipation surface that is opposite to the chip-bonding surface;
a chip disposed on the chip-bonding surface of the conductive substrate and having a plurality of connection pads that are arranged away from the conductive substrate;
a plurality of conductive spacers respectively disposed on the connection pads, wherein ends of the conductive spacers are arranged away from the conductive substrate and are coplanar with each other;
a lead frame connected to the ends of the conductive spacers in a flip-chip manner and having an exposed surface; and
an encapsulant covering the conductive substrate, the chip, the conductive spacers, and the lead frame, wherein the exposed surface and the heat-dissipation surface are exposed from the encapsulant.

12. The semiconductor package structure according to claim 11, wherein the exposed surface and the heat-dissipation surface are flush with an outer surface of the encapsulant.

13. The semiconductor package structure according to claim 11, wherein each of the conductive spacers has a coefficient of thermal expansion (CTE) that is less than 10 and that is less than two times of a CTE of the chip.

14. The semiconductor package structure according to claim 11, further comprising a plurality of conductive bonding layers, wherein any two of the conductive substrate, the chip, the conductive spacers, and the lead frame connected to each other are connected through one of the conductive bonding layers.

15. The semiconductor package structure according to claim 11, wherein the semiconductor package structure does not have any wiring structure covered by the encapsulant.

16. A semiconductor package structure, comprising:
a conductive substrate having a chip-bonding surface and a heat-dissipation surface that is opposite to the chip-bonding surface;
a plurality of conductive carriers arranged adjacent to the conductive substrate;
a chip disposed on the chip-bonding surface of the conductive substrate and having a plurality of connection pads that are arranged away from the conductive substrate;
a plurality of conductive spacers respectively disposed on at least one of the connection pads and at least one of the conductive carriers, wherein ends of the conductive spacers are coplanar with each other;
a lead frame connected to the ends of the conductive spacers in a flip-chip manner and having an exposed surface; and
an encapsulant covering the conductive substrate, the conductive carriers, the chip, the conductive spacers, and the lead frame, wherein the exposed surface, the heat-dissipation surface, and a surface of each of the conductive carriers are exposed from the encapsulant.

17. The semiconductor package structure according to claim 16, wherein the conductive spacers are respectively disposed on the connection pads and the conductive carriers.

18. The semiconductor package structure according to claim 17, further comprising a plurality of conductive bonding layers, wherein any two of the conductive substrate, the conductive carriers, the chip, the conductive spacers, and the lead frame connected to each other are connected through one of the conductive bonding layers.

19. The semiconductor package structure according to claim 16, further comprising a metal wire embedded in the encapsulant, wherein two ends of the metal wire are respectively connected to one of the connection pads and one of the conductive carriers.

20. The semiconductor package structure according to claim 16, wherein the conductive carriers are spaced apart from one side of the conductive substrate, and a thickness of each of the conductive carriers is greater than a thickness of the conductive substrate.
